(19) United States
(12) Patent Application Publication
(10) Pub. No.: US 2024/0344854 A1
(43) Pub. Date: Oct. 17, 2024

(54) NON-CONTACT TYPE OPTICAL ROCKER POTENTIOMETER

(71) Applicant: I-STAR ELECTRONICS CO LTD, Shenzhen (CN)

(72) Inventor: Xing TU, Shenzhen (CN)

(21) Appl. No.: 18/328,820

(22) Filed: Jun. 5, 2023

(30) Foreign Application Priority Data
Apr. 12, 2023 (CN) 202310388170.0

(51) Int. Cl. G01D 5/26; G01D 5/30

(52) U.S. Cl. CPC G01D 5/264; G01D 5/30

(57) ABSTRACT

Disclosed is a non-contact type optical rocker potentiometer, comprising a casing, a rocker and a rocker arm mechanism. The rocker arm mechanism is installed in the casing and is connected with one end of the rocker, and the other end of the rocker extends out of the casing, the rocker arm mechanism is provided with at least two steering output ends, the steering output end is provided with a light blocking part, two sides of the light blocking part are respectively provided with a light emitting element and a photosensitive element which are connected with a PCB board. The potentiometer has the advantages that problems of abrasion, fracture, poor contact accessories easily caused by a contact type potential regulating module are avoided, the stability of the potentiometer is enhanced, and the service life of the potentiometer is prolonged.

### CROSS REFERENCE TO RELATED APPLICATIONS

This application claims foreign priority of Chinese Patent Application No. 202310388170. 0, filed on Apr. 12, 2023 in the China National Intellectual Property Administration, the disclosures of all of which are hereby incorporated by reference.

### TECHNICAL FIELD

The present invention relates to a potentiometer, and in particular to a non-contact type optical rocker potentiometer.

### BACKGROUND OF THE PRESENT INVENTION

At present, an existing contact rocker potentiometer structure includes a casing, a rocker, a rocker arm mechanism and a potential regulating module. The rocker outputs a steering action through output ends of two rotating shafts of the rocker arm mechanism, and at the same time drives conductive reeds in the potential regulating module in two directions to rotate, thus changing a contact position of conductive terminals on the conductive reeds on a resistor chip, and further changing an output resistance value, thus judging a swing orientation of the rocker. For example, Chinese Patent Publication Number CN 210073523 U, entitled “Improved Rocker Potentiometer Structure”, Chinese Patent Publication Number CN 211858297 U, entitled “Rocker Potentiometer with Low Abrasion” and Chinese Patent Publication Number CN 210052601 U, entitled “Rocker Potentiometer Structure with Switch” all relate to contact type rocker potentiometer structures. As a contact type structure is employed in the potential regulating module of the contact type rocker potentiometer, problems such as abrasion, fracture and poor contact of accessories occur easily after a period of use, which will affect the normal use and service life of the potentiometer. Chinese Patent Publication Number CN 115631911 A, entitled “Optical Potentiometer Module” discloses a non-contact optical potentiometer module. However, the module is only suitable for “keys” but not for gamepad rocker. Therefore, developing a non-contact optical rocker potentiometer has become an urgent problem for those skilled in the art.

### SUMMARY OF PRESENT INVENTION

The present invention provides a non-contact type optical rocker potentiometer in order to solve the above shortages.

The above object of the present invention is achieved through the following technical solutions: a non-contact type optical rocker potentiometer comprises a casing, a rocker and a rocker arm mechanism, wherein the rocker arm mechanism is installed in the casing and is connected with one end of the rocker, and the other end of the rocker extends out of the casing, the rocker arm mechanism is provided with at least two steering output ends, the steering output end is provided with a light blocking part, two sides of the light blocking part are respectively provided with a light emitting element and a photosensitive element, and the light emitting element and the photosensitive element are connected with a PCB board.

Further, a size of a light area blocked by the light blocking part differs in an initial state when rotating clockwise to a limit position and counterclockwise to the limit position. Optionally, the light blocking part blocks half of the light in the initial state, and the light blocking part does not block the light and fully blocks the light respectively in the clockwise and counterclockwise limit positions, or the light blocking part fully blocks the light and does not blocks the light respectively in the clockwise and counterclockwise limit positions.

Further, the light emitting element, the photosensitive element and the PCB board are enclosed in a housing, and the housing is buckled on an outer wall of the casing.

Compared with the prior art, the present invention has the advantages that the oscillating direction of the rocker is judged by the cooperation of the light emitting element and the photosensitive element in a non-contact way based on the optical principle, so that problems of abrasion, fracture, poor contact and the like of accessories which are easily caused by a contact type potential regulating module are avoided, the stability of the potentiometer is enhanced, and the service life of the potentiometer is prolonged.

### DESCRIPTION OF THE DRAWINGS

FIG. 1 is a breakdown structural schematic diagram of a first embodiment of the present invention.

FIG. 2 is a breakdown structural schematic diagram of a second embodiment of the present invention.

FIG. 3 is a whole structural schematic diagram of the first embodiment of the present invention.

FIG. 4 is a whole structural schematic diagram of the second embodiment of the present invention.

FIG. 5 is a structural schematic diagram of a casing inside in the second embodiment of the present invention.

FIG. 6 is a schematic diagram of a working principle in the present invention.

FIG. 7 is a structural schematic diagram of a first embodiment of a light blocking part in the present invention.

FIG. 8 is a structural schematic diagram of a second embodiment of the light blocking part in the present invention.

FIG. 9 is a structural schematic diagram of a third embodiment of the light blocking part in the present invention.

FIG. 10 is a structural schematic diagram of a fourth embodiment of the light blocking part in the present invention.

FIG. 11 is a structural schematic diagram of a fifth embodiment of the light blocking part in the present invention.

FIG. 12 is a structural schematic diagram of a relative position among the fifth embodiment of the light blocking part and the light emitting element and the photosensitive element in the present invention.

FIG. 13 is a structural schematic diagram of another embodiment of the light blocking part in the present invention.

FIG. 14 is a structural schematic diagram of yet another embodiment of the light blocking part in the present invention.

### DETAILED DESCRIPTION OF PREFERRED EMBODIMENTS

The present invention will be further described in detail in conjunction with the accompanying drawing hereinafter.

### Embodiment 1

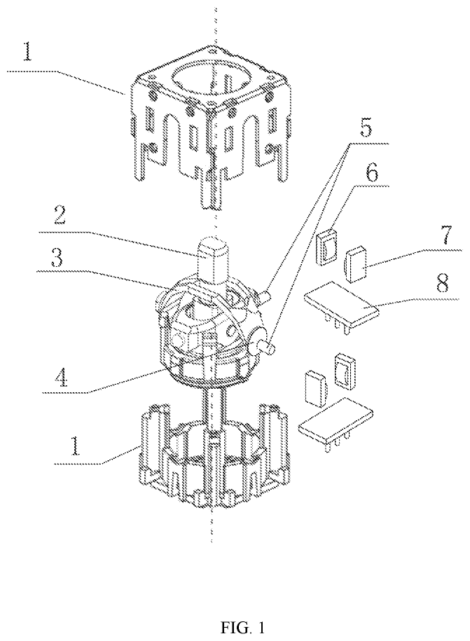

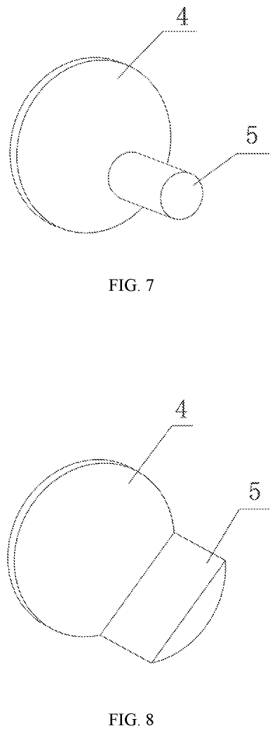

as shown in FIG. 1, a non-contact optical rocker potentiometer comprises a casing 1, a rocker 2 and a rocker arm mechanism 3. The rocker arm mechanism 3 is installed in the casing 1 and is connected with one end of the rocker 2, and the other end of the rocker 2 extends out of the casing 1. The rocker mechanism 3 is provided with at least two steering output ends 4, the steering output end 4 is provided with a light blocking part 5, the light blocking part 5 is cylindrical and eccentrically arranged on the end faces of the steering output ends 4 (FIG. 7). The light blocking part 5 blocks half of the light in an initial state, and the light blocking part 5 does not blocks the light and fully blocks the light respectively in the clockwise and counterclockwise limit positions, or the light blocking part 5 fully blocks the light and does not block the light respectively in the clockwise and counterclockwise limit positions, and two sides of the light blocking part 5 are respectively provided with a light emitting element 6 and a photosensitive element 7, the light emitting element 6 and the photosensitive element 7 are connected with a PCB board 8. The light-emitting element 6, the photosensitive element 7 and the PCB board 8 are installed inside an equipment shell (not shown in the figure, such as a gamepad shell) outside the casing 1, and the PCB board 8 is connected with an equipment motherboard in the equipment shell.

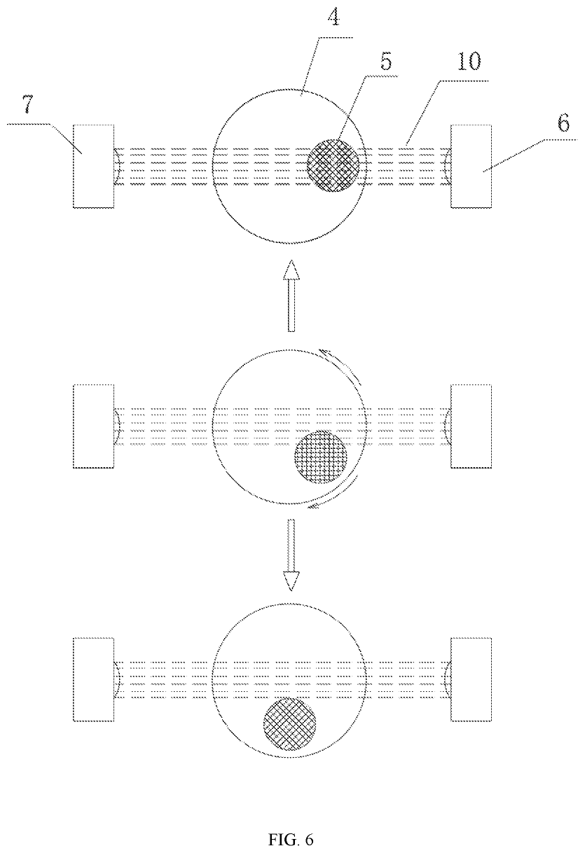

As shown in FIG. 6, when the rocker 2 swings, the rocker arm mechanism 3 drives the steering output end 4 to rotate clockwise or counterclockwise within a range of 45 degrees, thus driving the light blocking part 5 to rotate. When the rocker 2 swings to a certain orientation/angle, the corresponding steering output end 4 may generate a certain rotation angle, and the light blocking part 5 may rotate with the steering output end, so that the light blocking part 5 correspondingly blocks light rays 10 in different ranges (when the light blocking part blocks the light more, the light amount received by the photosensitive element 7 is low; on the contrary, when the light blocking part blocks less light, the light amount received by the photosensitive element 7 is high). A single chip microcomputer on the PCB board 8 analyzes and judges the swinging angle/orientation of the rocker through the light values received by the photosensitive elements 7 at two angles.

### Embodiment 2

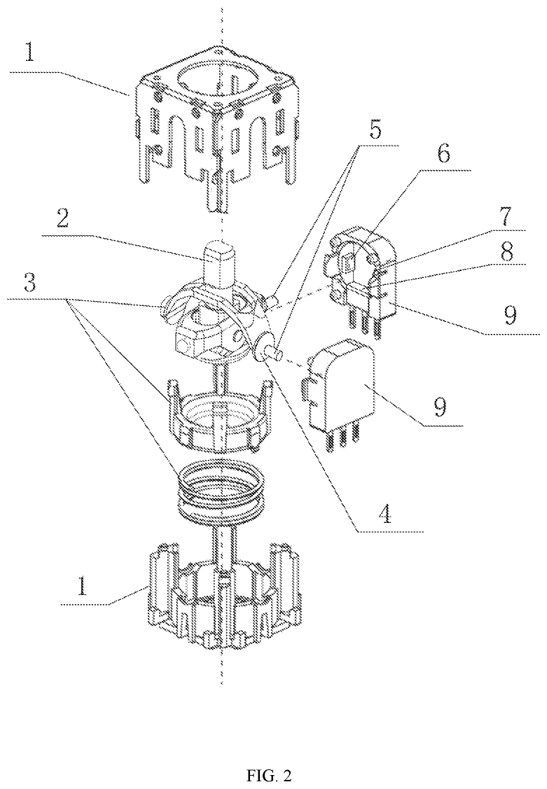

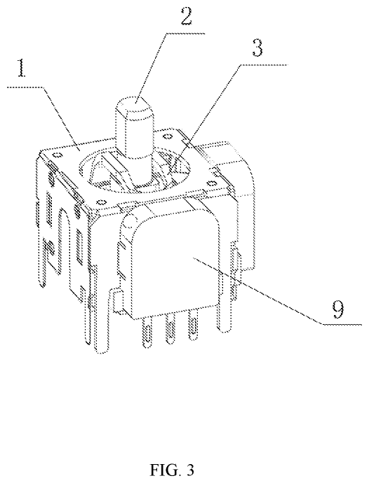

as shown in FIG. 2 and FIG. 3, a non-contact optical rocker potentiometer comprises a casing 1, a rocker 2 and a rocker arm mechanism 3. The rocker arm mechanism 3 is installed in the casing 1 and is connected with one end of the rocker 2, and the other end of the rocker 2 extends out of the casing 1. The rocker mechanism 3 is provided with at least two steering output ends 4, the steering output end 4 is provided with a light blocking part 5, the light blocking part 5 is cylindrical and eccentrically arranged on the end faces of the steering output ends 4 (FIG. 7). The light blocking part 5 blocks half of the light in an initial state, and the light blocking part 5 does not blocks the light and fully blocks the light respectively in the clockwise and counterclockwise limit positions, or the light blocking part 5 fully blocks the light and does not block the light respectively in the clockwise and counterclockwise limit positions, and two sides of the light blocking part 5 are respectively provided with a light emitting element 6 and a photosensitive element 7, the light emitting element 6 and the photosensitive element 7 are connected with a PCB board 8. The light-emitting element 6, the photosensitive element 7, the PCB board 8 and the light blocking part are enclosed in a housing 9, and the housing 9 is buckled on an outer wall of the casing 1.

### Embodiment 3

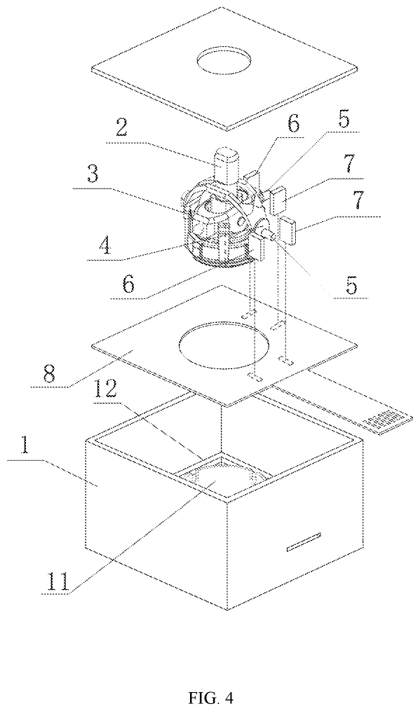

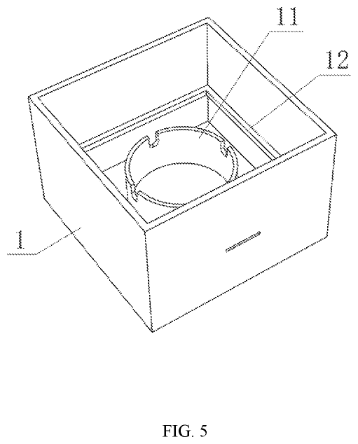

as shown in FIG. 4 and FIG. 5, a non-contact optical rocker potentiometer comprises a casing 1, a rocker 2 and a rocker arm mechanism 3. The rocker arm mechanism 3 is installed in a rocker arm mechanism mounting base 11 in the casing 1 and is connected with one end of the rocker 2, and the other end of the rocker 2 extends out of the casing 1. The rocker mechanism 3 is provided with at least two steering output ends 4, the steering output end 4 is provided with a light blocking part 5, the light blocking part 5 is cylindrical and eccentrically arranged on the end faces of the steering output ends 4 (FIG. 7). The light blocking part 5 blocks half of the light in an initial state, and the light blocking part 5 does not blocks the light and fully blocks the light respectively in the clockwise and counterclockwise limit positions, or the light blocking part 5 fully blocks the light and does not block the light respectively in the clockwise and counterclockwise limit positions, and two sides of the light blocking part 5 are respectively provided with a light emitting element 6 and a photosensitive element 7, the light emitting element 6 and the photosensitive element 7 are connected with a PCB board 8 and are mounted on a circuit bard mounting base 12 in the casing 1 together with the PCB board 8.

### Embodiment 4

as shown in FIG. 8, the light blocking part 5 is an arched column, which is eccentrically arranged on the end face of the steering output end 4 and is integrally connected to the end face edge of the steering output end 4. The other structures of this embodiment are the same as those of Embodiment 1, Embodiment 2 or Embodiment 3 except for the light blocking part 5.

### Embodiment 5

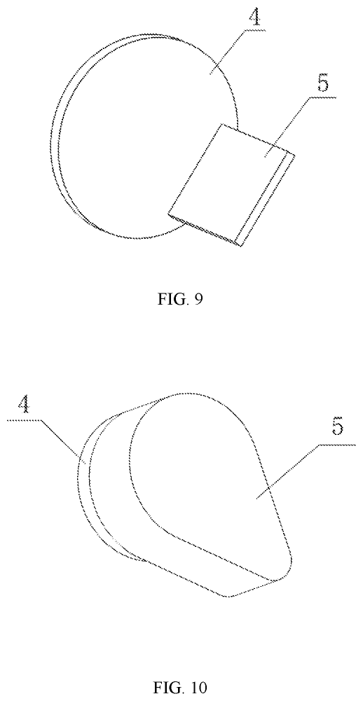

as shown in FIG. 9, the light blocking part 5 is plate-shaped and is eccentrically arranged on the end face of the steering output end 4. The other structures of this embodiment are the same as those of Embodiment 1 or Embodiment 2 except for the light blocking part 5.

### Embodiment 6

as shown in FIG. 10, the light blocking part 5 is cam-shaped and is eccentrically arranged on the end face of the steering output end 4. The other structures of this embodiment are the same as those of Embodiment 1 or Embodiment 2 except for the light blocking part 5.

### Embodiment 7

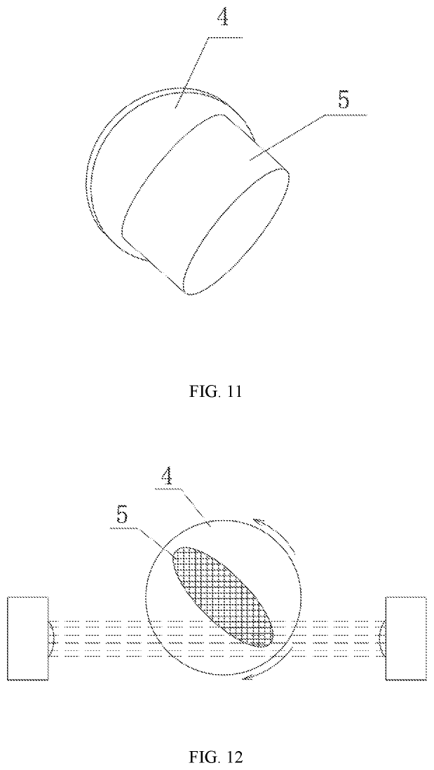

as shown in FIG. 11 and FIG. 12, the light blocking part 5 is elliptical and is concentrically arranged on the end face of the steering output end 4, but needs to be misplaced relative to the light emitting element 6 and the photosensitive element 7, so as to meet the condition that the size of the light blocking part 5 is different when the light blocking part 5 rotates in the initial state or clockwise to the limit position and counterclockwise to the limit position. The other structures of this embodiment are the same as those of Embodiment 1 or Embodiment 2 except for the light blocking part 5.

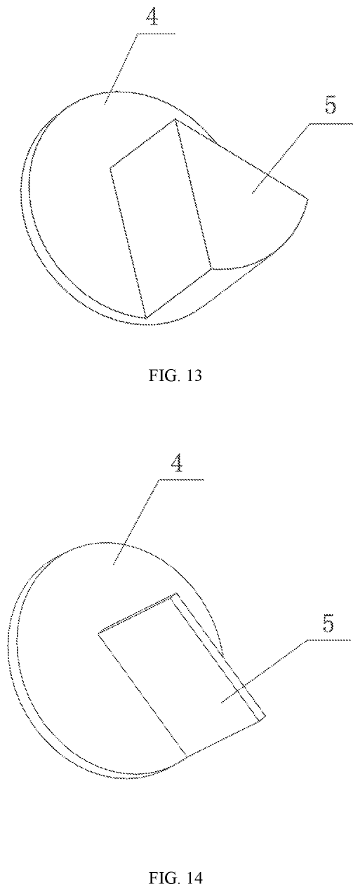

The specific shape of the light blocking part 5 is not limited to the scope of the above-mentioned embodiments, but also can be in various other shapes, as shown in FIG. 13 and FIG. 14, as long as it is satisfied that the size of the light blocking area is different when the light blocking part 5 rotates in the initial state or clockwise to the limit position and counterclockwise to the limit position.

Those mentioned above are only the embodiments of the present invention, which do not limit the patent scope of the present invention. Any equivalent structure or equivalent process transformation made by using the contents of the description and drawings of the present invention, or directly or indirectly applied to other related technical fields, are equally included in the patent protection scope of the present invention.

We claim:

1. A non-contact type optical rocker potentiometer, comprising a casing, a rocker and a rocker arm mechanism, wherein the rocker arm mechanism is installed in the casing and is connected with one end of the rocker, and the other end of the rocker extends out of the casing, the rocker arm mechanism is provided with at least two steering output ends, the steering output end is provided with a light blocking part, two sides of the light blocking part are respectively provided with a light emitting element and a photosensitive element, and the light emitting element and the photosensitive element are connected with a PCB board.

2. The non-contact type optical rocker potentiometer according to claim 1, wherein a size of a light area blocked by the light blocking part differs in an initial state when rotating clockwise to a limit position and counterclockwise to the limit position.

3. The non-contact type optical rocker potentiometer according to claim 1, wherein the light blocking part blocks half of the light in the initial state, and the light blocking part does not block the light and fully blocks the light respectively in the clockwise and counterclockwise limit positions, or the light blocking part fully blocks the light and does not blocks the light respectively in the clockwise and counterclockwise limit positions.

4. The non-contact type optical rocker potentiometer according to claim 1, wherein the PCB board is installed inside an equipment shell outside the casing together with the light emitting element and the photosensitive element.

5. The non-contact type optical rocker potentiometer according to claim 1, wherein the light emitting element, the photosensitive element and the PCB board are enclosed in a housing, and the housing is buckled on an outer wall of the casing.

6. The non-contact type optical rocker potentiometer according to claim 1, wherein the PCB board is installed in the casing together with the light emitting element and the photosensitive element.
